(19) United States
(12) Patent Application Publication
(10) Pub. No.: US 2005/0157391 A1
(43) Pub. Date: Jul. 21, 2005

(54) Diffractive optical element

(75) Inventor: Ronald Wilklow, Fairfield, CT (US)

Correspondence Address: STERNE, KESSLER, GOLDSTEIN & FOX PLLC, 1100 NEW YORK AVENUE, N.W., WASHINGTON, DC, 20005, US

(73) Assignee: ASML Holding N.V., Veldhoven (NL)

(21) Appl. No.: 11/041,409

(22) Filed: Jan. 25, 2005

Related U.S. Application Data
(62) Division of application No. 10/625,704, filed on Jul. 24, 2003.

(51) Int. Cl. G03F 9/00

(52) U.S. Cl. 359/566

(57) ABSTRACT

A diffraction element can be used in a system employing very short wavelengths of light, for example light in the nanometer range (e.g., about 100 nm to about 300 nm). The diffraction element is formed using a substrate (or any optical element) having high transmission characteristics in this wavelength range. For example, calcium fluoride or barium fluoride can be used. A layer of amorphous isotropic material, such as silicon dioxide or silica, is deposited on the substrate and patterned to allow for diffraction.

### CROSS-REFERENCE TO RELATED APPLICATIONS

This application is a divisional application of U.S. Ser. No. 10/625,704, filed Jul. 24, 2003, which is incorporated by reference herein in its entirety.

### BACKGROUND OF THE INVENTION

1. Field of the Invention

The present invention relates generally to diffraction elements, which are used in lithography systems employing very short wavelengths of light during exposure.

2. Related Art

Lithography is a process used to create features on the surface of substrates. Such substrates can include those used in the manufacture of flat panel displays (e.g., liquid crystal displays), circuit boards, various integrated circuits, and the like. A frequently used substrate for such applications is a semiconductor wafer or glass substrate. While this description is written in terms of a semiconductor wafer for illustrative purposes, one skilled in the art would recognize that this description also applies to other types of substrates known to those skilled in the art.

During lithography, a wafer, which is disposed on a wafer stage, is exposed to an image projected onto the surface of the wafer by exposure optics located within a lithography apparatus. While exposure optics are used in the case of photolithography, a different type of exposure apparatus can be used depending on the particular application. For example, x-ray, ion, electron, or photon lithography each can require a different exposure apparatus, as is known to those skilled in the art. The particular example of photolithography is discussed here for illustrative purposes only.

The projected image produces changes in the characteristics of a layer, for example photoresist, deposited on the surface of the wafer. These changes correspond to the features projected onto the wafer during exposure. Subsequent to exposure, the layer can be etched to produce a patterned layer. The pattern corresponds to those features projected onto the wafer during exposure. This patterned layer is then used to remove or further process exposed portions of underlying structural layers within the wafer, such as conductive, semiconductive, or insulative layers. This process is then repeated, together with other steps, until the desired features have been formed on the surface, or in various layers, of the wafer.

Step-and-scan technology works in conjunction with a projection optics system that has a narrow imaging slot. Rather than expose the entire wafer at one time, individual fields are scanned onto the wafer one at a time. This is accomplished by moving the wafer and reticle simultaneously such that the imaging slot is moved across the field during the scan. The wafer stage must then be asynchronously stepped between field exposures to allow multiple copies of the reticle pattern to be exposed over the wafer surface. In this manner, the quality of the image projected onto the wafer is maximized.

Conventional lithographic systems and methods form images on a semiconductor wafer. The system typically has a lithographic chamber that is designed to contain an apparatus that performs the process of image formation on the semiconductor wafer. The chamber can be designed to have different gas mixtures and/or grades of vacuum depending on the wavelength of light being used. A reticle is positioned inside the chamber. A beam of light is passed from an illumination source (located outside the system) through an optical system, an image outline on the reticle, and a second optical system before interacting with a semiconductor wafer.

Conventional systems can use diffraction elements in the optical system in order to distribute the illumination energy from the light source. However, normal materials used to form the diffraction elements tend to absorb light at wavelengths in the nanometer range (e.g., about 100 nm to about 300 nm). Further, materials that have substantially little attenuation, such as calcium fluoride, cannot effectively be used as a diffraction element. This is because their crystalline nature results in anisotropic etching when trying to pattern the diffraction pattern on its surface. One material that can be used to solve this problem is doped fused silica. Unfortunately, this material lowers transmission of light through the optical system and has a high potential for laser degradation.

Therefore, what is needed is a diffraction element that can be used in systems utilizing very short wavelengths of light, such as in the nanometer range (e.g., about 100 nm to about 300 nm), that do not exhibit the characteristics noted above.

### SUMMARY OF THE INVENTION

An embodiment of the present invention provides a method including providing a substrate (e.g., made of calcium fluoride, barium fluoride, etc.) that transmits light having wavelengths of about 100 nm to about 300 nm. Forming an amorphous isotropic layer (e.g., made of silicon dioxide, etc.) on the substrate, which transmits the light at wavelengths in the ranges without substantial attenuation of the light. Patterning the layer and removing a portion of the layer from regions of the substrate based on the patterning, such that a diffraction element is formed.

Another embodiment of the present invention provides a diffraction element configured to transmit light having a wavelength of about 100 nm to about 300 nm. The diffraction element including a substrate allowing relatively low attenuation of the light during transmission and an amorphous isotropic structure pattered on a surface of the substrate.

A further embodiment of the present invention provides a lithography system configured to pattern substrates with light having a wavelength of about a nanometer range (e.g., about 100 nm to about 300 nm). The lithography system includes a diffraction element made of a material that transmits the light. The diffraction element includes a substrate allowing relatively low attenuation of the light during transmission and an amorphous isotropic structure pattered on a surface of the substrate.

A still further embodiment of the present invention provides a method of forming a diffraction element that transmits light having a wavelength in a nanometer range (e.g., about 100 nm to about 300 nm). The method includes providing a substrate, forming an amorphous isotropic layer on the substrate, forming a resist layer on the amorphous isotropic layer, patterning the resist layer, removing a portion of the resist layer based on the patterning, patterning the amorphous isotropic layer based on the previous patterning step, and removing a remaining portion of the resist layer.

A still further embodiment of the present invention provides a method of forming a diffraction element that transmits light having a wavelength in a nanometer range (e.g., about 100 nm to about 300 nm). The method includes providing a substrate, forming a resist layer, patterning the resist layer, removing a portion of the resist layer based on the patterning, forming an amorphous isotropic layer on the patterned resist layer, polishing the amorphous isotropic layer, and removing a remaining portion of the resist layer.

Further embodiments, features, and advantages of the present inventions, as well as the structure and operation of the various embodiments of the present invention, are described in detail below with reference to the accompanying drawings.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a lithography system according to embodiments of the present invention

FIGS. 2, 3, 4, 5, 6, and 7 show steps of making a diffraction element according to an embodiment of the present invention.

FIGS. 8, 9, 10, 11, 12, and 13 show steps of making a diffraction element according to another embodiment of the present invention.

The present invention will now be described with reference to the accompanying drawings. In the drawings, like reference numbers may indicate identical or functionally similar elements. Additionally, the left-most digit(s) of a reference number may identify the drawing in which the reference number first appears.

### DETAILED DESCRIPTION OF THE INVENTION

Overview

While specific configurations and arrangements are discussed, it should be understood that this is done for illustrative purposes only. A person skilled in the pertinent art will recognize that other configurations and arrangements can be used without departing from the spirit and scope of the present invention. It will be apparent to a person skilled in the pertinent art that this invention can also be employed in a variety of other applications.

The present invention provides a diffraction element that can be used in a system employing very short wavelengths of light, for example light in the nanometer range (e.g., about 100 nm to about 300 nm). The diffraction element is formed using a substrate having high transmission characteristics in this wavelength range. For example, calcium fluoride or barium fluoride can be used. A patterned layer of amorphous isotropic material, such as silicon dioxide, is formed on the substrate to allow for diffraction.

The layer can be thin enough, for example substantially equal to a wavelength of light being used, to have insignificant absorption at nanometer wavelengths (e.g., about 100 nm to about 300 nm). Laser damage in such a thin layer will be inconsequential. A thickness of the layer can be precisely controlled and uniform. The substrate can function as a stop for a thickness of the diffraction element because most removal processes used for the layer will not remove the substrate. In this case, a thickness of the layer can be a thickness of the pattern. This results in more efficient fabrication and excellent control of fabrication tolerances.

While the diffraction element is described in relation to being in an illumination system of a lithography tool, as will be understood by one of ordinary skill in the art, the diffraction element can be used in any system employing light in the short wavelength range (e.g., about 100 nm to about 300 nm), such as a holography system, a metrology system, an illumination system, or the like. Also, it is to be appreciated that although described as being a diffraction grating on a substrate, the diffraction grating can be added to any optical element within an optical system, for example a lens or a mirror, without departing from the scope of the present invention.

Overall System

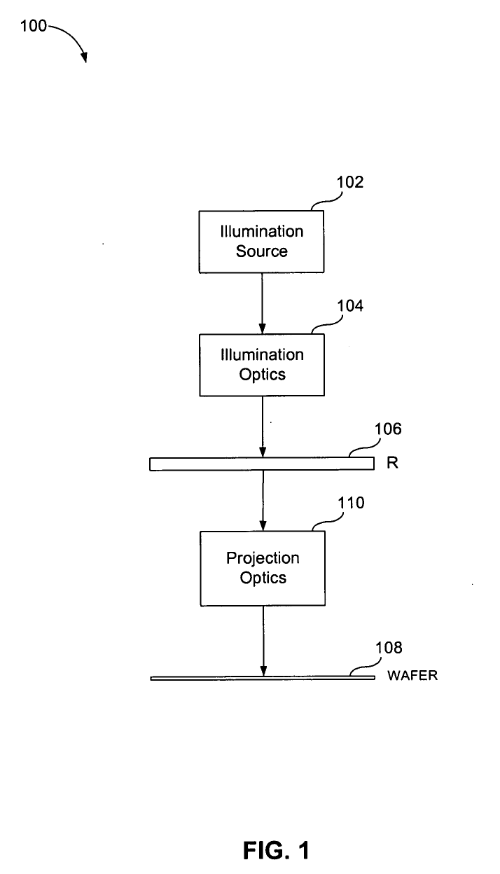

FIG. 1 shows a system 100 according to an embodiment of the present invention. System 100 includes an illumination source 102 that outputs light to illumination optics 104. Illumination optics 104 direct the light through (or off) a mask or reticle 106 onto a substrate 108 via projection optics 110. One embodiment for this system can be a lithography system, or the like. Another embodiment can be a holography system. Illumination optics 104 can include a diffraction element (not shown, but element 700 (FIG. 7) or element 1300 (FIG. 13) are examples, which are discussed in more detail below) that can be used to help re-distribute the illumination energy.

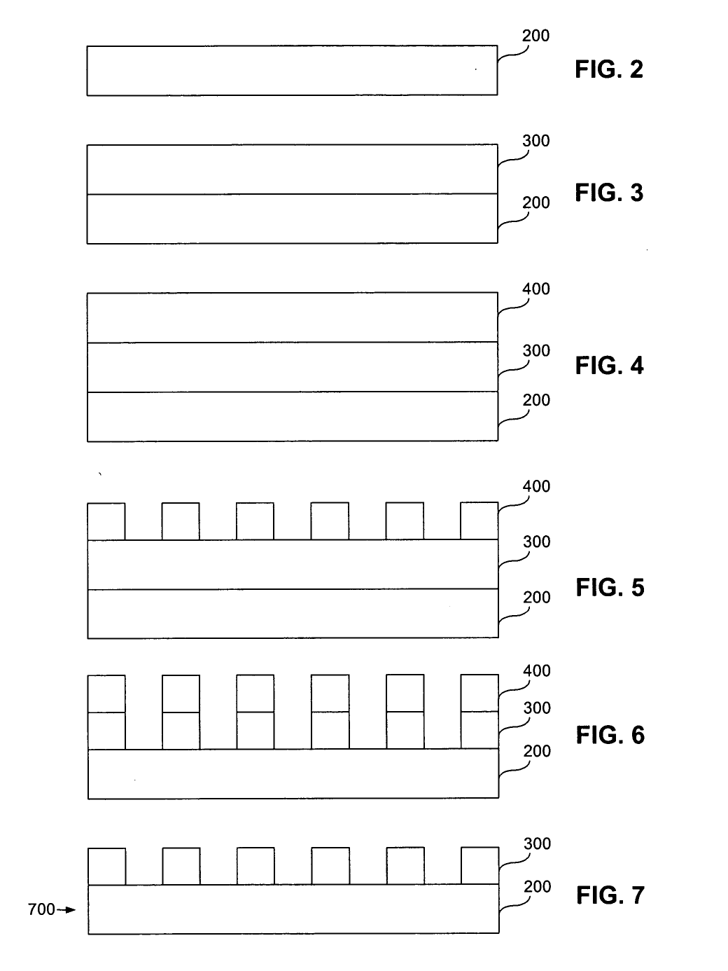

Example fabrication process embodiments for fabricating a diffraction element are shown below for diffraction elements 700 and/or 1300, respectively, in reference to FIGS. 2-7 and FIGS. 8-13. It is to be appreciated, other processes can also be used to make a diffraction element, which are contemplated within the scope of the present invention.

FIG. 2 shows a first fabrication step for making a diffraction element 700. A substrate 200 is provided, which can be made of calcium fluoride (CaF₂), barium fluoride (BaF₂), or the like. Substrate 200 can have a thickness in a range of about 1 mm to about 6 mm, which can be implementation specific. It is to be appreciated that a type of material used to make substrate 200 can be based on a wavelength of light being used in an optical system. For example, the above materials can be used with vacuum ultra violet (VUV) systems using 157 nm, 193 nm, and/or 248 nm light. Thus, any appropriate other materials can be used based on the wavelength of light.

FIG. 3 shows a second fabrication step for making the diffraction element 700. Substrate 200 is shown after a layer 300 has been formed on a surface of substrate 200. Forming can be based on depositing material using sputtering, chemical vapor deposition, evaporation, or the like. Layer 300 is an amorphous, isotropic structure. For example, layer 200 can be formed from silicon dioxide (SiO₂), silica, or the like. This material may be advantageous to use because it has well established removal (e.g., etching) processes and chemistry. It is to be appreciated that other materials could also be employed, as would be known to one of ordinary skill in the art. A thickness of layer 300 can be based on a phase difference required for the diffraction effect desired. This would be less than or approximately equal to the wavelength of light for which the device is designed. For example, a thickness of about 100 nm to about 300 nm can be used.

FIG. 4 shows a third fabrication step for making diffraction element 700. A resist layer 400 is formed on the layer 300. Forming can be based on depositing known resist material using known processes, as discussed above. Resist layer 400 can be of any thickness and made from materials known in the art to perform functions as described above.

FIG. 5 shows a fourth step for making diffraction element 700. A portion of resist layer 400 is removed based on a previously formed pattern. Removal can be accomplished via etching or any other known process.

FIG. 6 shows a fifth step for making element 700. A portion of layer 300 is removed based on the portion of resist 400 that was previously removed. Removal can be accomplished via etching or any other known process. Substrate 200 can act as a stop if it is made of material resistant to a process used to remove the portion of layer 300. Thus, a thickness of layer 200 above a surface of substrate 200 can be precisely controlled.

FIG. 7 shows a sixth step for making diffraction element 700. Diffraction element 700 is shown after a remaining portion of resist layer 400 has been removed. Similar processes to those described above for removing the first portion of resist 400 can be used to remove the remaining portion of resist layer 400.

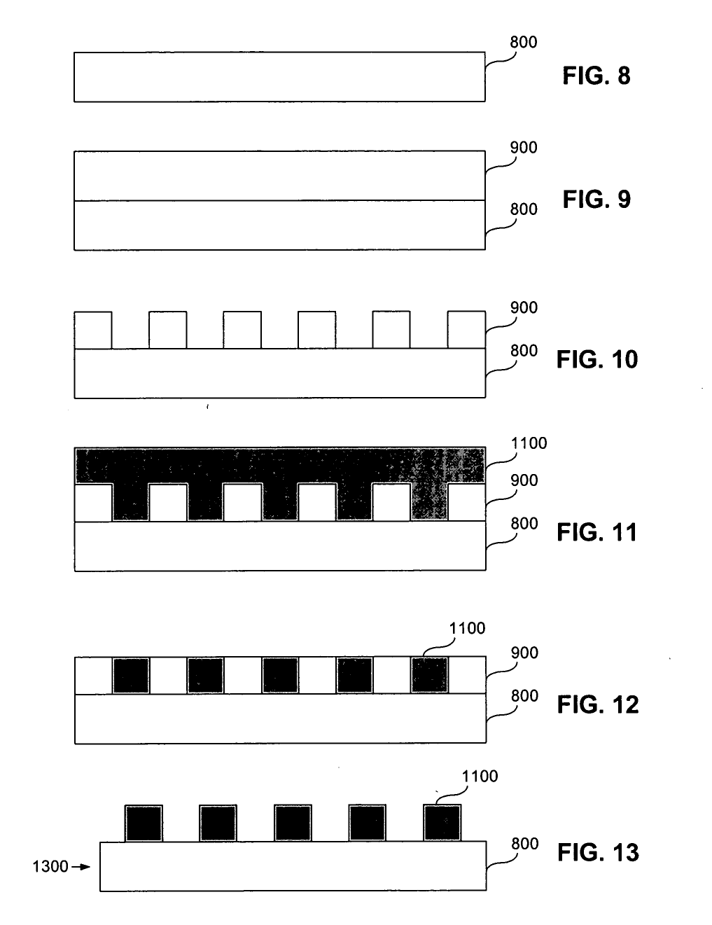

FIG. 8 shows a first fabrication step for making a diffraction element 1300. A substrate 800 is provided, which can be made of calcium fluoride (CaF₂), barium fluoride (BaF₂), or the like. Substrate 800 can have a thickness in a range of about 1 mm to about 6 mm. It is to be appreciated that a type of material used to make substrate 800 can be based on a wavelength of light being used in an optical system. For example, the above materials can be used with vacuum ultra violet (VUV) systems using 157 nm, 193 nm, and/or 248 nm light. Thus, any appropriate other materials can be used based on the wavelength of light.

FIG. 9 shows a second fabrication step for making the diffraction element 1300. Substrate 800 is shown after a resist layer 900 has been formed onto a surface of substrate 800. Forming can be based on depositing known resist material using known processes, as discussed above. Resist layer 900 can be of any thickness and made from materials known in the art to perform functions as described above.

FIG. 10 shows a third fabrication step for making the diffraction element 1300. A portion of resist layer 800 has been removed based on a previously formed pattern. Removal can be accomplished via etching or any other known process.

FIG. 11 shows a fourth fabrication step for making the diffraction element 1300. A layer 1100 has been formed on a portion of a surface of substrate 800 and surfaces of remaining portions of resist layer 900. The forming can be based on depositing material using sputtering, chemical vapor deposition, evaporation, or the like. Layer 1100 is an amorphous, isotropic structure. For example, layer 1100 can be formed from silicon dioxide (SiO₂), silica, or the like. This material may be advantageous to use because it has well established removal (e.g., etching) processes and chemistry. It is to be appreciated that other materials could also be employed, as would be known to one of ordinary skill in the art.

FIG. 12 shows a fifth fabrication step for making the diffraction element 1300. A portion of layer 1100 is removed via polishing, or the like. The amount removed is based on a thickness of resist layer 900.

FIG. 13 shows a sixth fabrication step for making the diffraction element 1300. A remaining portion of resist layer 900 is removed, leaving a patterned layer 1100. The removal can be via etching, or the like. A final thickness of layer 1100 can be based on a phase difference required for the diffraction effect desired. This would be less than or approximately equal to the wavelength of light for which the device is designed. For example, a thickness of about 100 nm to about 300 nm can be used.

### Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

1. A diffraction element configured to transmit light having a wavelength in about a nanometer range comprising:
a substrate allowing relatively low attenuation of the light during transmission; and
an amorphous isotropic structure pattered on a surface of the substrate.

2. The diffraction element of claim 1, wherein the substrate comprises calcium fluoride.

3. The diffraction element of claim 1, wherein the substrate comprises barium fluoride.

4. The diffraction element of claim 1, wherein the pattern is formed from a silicon dioxide layer.

5. The diffraction element of claim 1, wherein the small wavelengths of light are about 100 nm to about 300 nm.

6. The diffraction element of claim 1, wherein the light is about one of extreme ultra violet, deep ultra violet, and vacuum ultraviolet range.

7. A lithography system configured to pattern substrates with light having a wavelength of about a nanometer range, the lithography system including a diffraction element made of a material that transmits the light, the diffraction element comprising:
a substrate allowing relatively low attenuation of the light during transmission; and
an amorphous isotropic structure pattered on a surface of the substrate.

8. The lithography system of claim 7, further comprising an illumination system, wherein the diffraction grating is located in the illumination system.
